(19) United States
(12) Patent Application Publication
(10) Pub. No.: US 2009/0114430 A1
(43) Pub. Date: May 7, 2009

(54) METHOD FOR PATTERNING OF CONDUCTIVE POLYMER

(75) Inventor: Jin Yeol KIM, Anyang-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Industry Academic Cooperation Foundation of Kukmin University, Seoul (KR)

(21) Appl. No.: 11/935,680

(22) Filed: Nov. 6, 2007

(51) Int. Cl. H05K 1/09; G03C 5/00

(52) U.S. Cl. 174/257; 430/314

(57) ABSTRACT

Disclosed herein is a method of patterning a circuit using a self-assembly lithography. More specifically, the present invention is directed to a method of a circuit by a self-assembly lithography, which comprises the steps of: coating a substrate; forming the primary circuit; completing the patterning; and washing the substrate, a self-assembled lithographic circuit prepared by said method, and a method of forming an electrode circuit using said circuit. The inventive method of patterning a circuit using a self-assembly lithography is a new patterning process which does not use any typical photoresists and developers, thereby greatly reducing the manufacturing cost. Further, the inventive method converts the conventional top-down process into a bottom-up process, which enables to form more fine circuits with freedom. The circuit prepared according to the present invention can be effectively used for the photo process in a semiconductor and a display.

### BACKGROUND OF THE INVENTION

1. Field of the Invention

The present invention relates to a method of patterning a circuit polymer. More specifically, the present invention relates to a method of patterning a circuit using a self-assembly lithography which comprises the steps of: preparing a coated substrate; forming a primary circuit on the substrate; completing the patterning of the circuit; and washing the substrate, a self-assembled lithographic circuit prepared by said method, and a method of forming an electrode circuit using said circuit.

2. Background of the Related Art

Up to date, a patterning process using a lithographic technique has been used for the preparation of semiconductors or electronic parts. However, the conventional process has a technical and economical limitation in preparing nano-sized elements which are now actively studied for the preparation of highly precise semiconductor components, and thus a new patterning process is greatly needed. Particularly, since in the traditional photo lithography a resolution of patterning is inversely proportional to a wavelength of light, the wavelength of light should be shortened so as to produce a high resolution of patterning. When a short wavelength of light is used, since an absorbance of the photoresist which is a mixture with photosensitive polymers increases, the thickness of photoresist should be very thin and the substrate should be evenly covered with the photoresist. In order to have an evenly coated photoresist film without any crevice, a thickness of the film should be minimally over several microns. The way suggested to solve said problems is to use an organic monolayer and a self-assembled organic monolayer is the most ideal to provide a uniform organic film in the thickness of several nm. However, materials such as the alkyl silan compounds which have been used for the preparation of the self-assembled monolayer have no self-activity to UV light. When patterned by the traditional photolithography using the materials, the working time is long and much energy is consumed, thus increasing the manufacturing cost.

A conventionally used process for patterning a circuit in the field of semiconductor or display is a photolithography which needs to use photosensitive polymers as well as developers and is carried out by a wet process because the materials are liquid. Since the thickness of the coating should be maintained a minimum size over several μm, the process has a limitation in the preparation of extremely fine circuits. Such photolithography is a representative top-down process which comprises coating the substrate with a thick film of photosensitive polymer, selectively exposing the substrate to UV light and then selectively dissolving the exposed and non-exposed portions in a developing step. The process needs a high investment and makes the cost of materials increased. In addition, an environmental problem is severe because a large of amount of organic solvents are used. However, until now a suitable process to replace the conventional process has not been developed, and thus, the conventional process is used in a most manufacturing and developing process.

With an effort for searching a process for the preparation of a circuit in a simple way without using photosensitive polymers and developers, the present inventors have completed the present invention by developing a new method of patterning a circuit using a self-assembly lithography through a bottom-up process and demonstrating that the method can be effectively utilized in the field of semiconductor and display.

### SUMMARY OF THE INVENTION

An object of the present invention is to provide a method of patterning a circuit using a self-assembly lithography through a bottom-up process, which produces various patterns of high-molecule thin film in a simple CVD method without using any photoresists and developers. In contrast to the inventive method, the traditional patterning method is carried out by a photolithography through a top-down process with photoresists and developers.

Another object of the present invention is to provide a self-assembled lithographic circuit prepared by said method.

Yet another object of the present invention is to provide a method of using the self-assembled lithographic circuit.

### DETAILED DESCRIPTION OF THE PREFERRED EMBODIMENT

To accomplish said object, the present invention provides a method of patterning a circuit using a self-assembly lithography, which comprises the steps of: coating a substrate with a photosensitive inorganic oxidant which acts as a catalyst or an oxidant in the thickness of nanometer (nm); irradiating selective UV or visible light with a stepper to the coated substrate on which a photomask with a circuit pattern is placed to thereby form a primary circuit on the portion exposed to the UV or visible light; contacting the substrate having the primary circuit with monomers in a phase of vapor and growing a polymeric thin film selectively on the portion exposed to and the portion non-exposed to the UV or visible light in a surface of the substrate to thereby complete the circuit patterning; and washing the patterned substrate to thereby remove impurities or non-reacted materials.

Further, the present invention provides a self-assembled lithographic circuit having an electric conductivity prepared by said method.

Furthermore, the present invention provides a method of forming an electrode circuit wherein the self-assembled lithographic circuit is used as a material for an electronic part, a flat panel display or a semiconductor process.

The present invention is illustrated in detail as follows:

The present invention provides a method of patterning a circuit using a self-assembly lithography, which comprises the steps of: i) coating a substrate with a photosensitive inorganic oxidant which acts as a catalyst or an oxidant in the thickness of nanometer (nm); (ii) irradiating selective UV or visible light with a stepper to the coated substrate on which a photomask with a circuit pattern is placed to thereby form a primary circuit on the portion exposed to the UV or visible light; (iii) contacting the substrate having the primary circuit with monomers in a phase of vapor and growing a polymeric thin film selectively on the portion exposed to and the portion non-exposed to the UV or visible light in a surface of the substrate to thereby complete the circuit patterning; and (iv) washing the patterned substrate to thereby remove impurities or non-reacted materials.

In the inventive method, after coating a substrate with a photosensitive inorganic oxidant for the preparation of coated substrate, the substrate is preferably dried by a drier. Specifically, the substrate coated with said oxidant is dried in a drier of 30 to 80° C. for 0.1 to 8 minutes.

Preferably, the substrate is selected from the group consisting of a glass, a silicon wafer, a metal and a plastic and, more preferably, the substrate is formed of a transparent plastic which is selected from the group consisting of polyester (PET), polycarbonate (PC), polyimide (PI), polyethersulfone (PES), TAC, COC polymer and polyester.

The photosensitive inorganic oxidant preferably comprises a copper oxidant or a ferric compound (Fe⁺³). More preferably, the oxidant is selected from the group consisting of CuCl₃, Cu(ClO₄)₂.6H₂O, FeCl₃ and ferric p-toluene sulfonate. Specifically, it includes Irgacure, CuCl₃, FeCl₃, Cu(ClO₄)₂.6H₂O (copper(II) perchloratehexa-hydrate), ferric p-toluene sulfonat and the like, and is prepared by dissolving it into an organic solvent which is selected from methyl alcohol, ethyl alcohol, cyclohexane, acetone, 2-butyl alcohol, ethylacetate, toluene, ethylcellosolve and the like. The solvent is used alone or as a mixture of 2 to 3 solvents, for example, a mixture of methyl alcohol, 2-butyl and ethylcellosolve in a ratio of 7:2:1, 6:2:2, 6:3:1 or 5:3:2. The photosensitive inorganic oxidant is used in an amount of 0.5 to 10% by weight based on the total weight of the organic solvent.

In order to enhance the adhesion of the photosensitive inorganic oxidant to a substrate, it is preferred to further add the other host polymer material to the oxidant. Preferably, the host polymer material is selected from the group consisting of polybutylacrylate, polycarbonate, polyurethane, polyvinylchloride, polyvinylalcohol, polyester, methylcellulose and chitosan, wherein the host polymer is preferably added in an amount of 0.5 to 10% by weight based on the total weight of the photosensitive oxidant.

The stepper preferably uses an electron beam or a plasma. The wavelength of UV or visible light irradiated by stepper is preferably within a range of 100 to 500 nm.

The monomer in a vapor phase is preferably selected from the group consisting of aniline, pyrrol, thiophene, furan, selenophene, 2,3-dihydrothio-3,4-dioxin (EDOT) and derivatives thereof and, also, the other acryl monomer, imides and the like can be used.

The monomer is vaporized by a distillation of the monomer in a closed chamber at a temperature of 10 to 100° C. or by the use of chemical vapor deposition (CVD) device. Preferably, contacting the substrate having the primary circuit with the monomers in a vapor phase is performed in a CVD chamber. More preferably, in order to form the self-assembled polymer, the monomer vaporized in the CVD chamber is contacted with the substrate coated with the oxidant. When the substrate coated with the oxidant is contacted with the monomers vaporized in the CVD chamber, the self-assembly polymerization occurs. The reaction temperature is 0 to 100° C. and the reaction time is 5 seconds to 40 minutes.

The non-reacted materials are preferably removed by an organic solvent or water. The organic solvent is preferably selected from the group of alcohol such as methanol and acetone. Each steps for the inventive method can be carried out by a non-continuous process, or a continuous process. That is, the non-reacted monomers and oxidants are washed with an organic solvent such as alcohol including methanol or water. UV light can be irradiated during the process of the self-assembly polymerization.

The primary circuit of photosensitive inorganic oxidant can be formed by a contact printing process or an ink-jet printing process, instead of the formation of the primary circuit disclosed above. It is preferred that the completion of patterning is accomplished by growing polymeric thin film selectively on only the oxidant-coated substrate.

The conductive polymer material of the circuit prepared by the self-assembly synthesis has a chemical structure of the following formula 1:

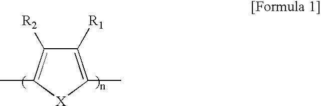

wherein, X is selected from the group consisting of sulfur (S), oxygen (O), selenium (Se) and NH; each of R1 and R2 is selected from the group consisting of a hydrogen atom, an alkyl group containing 3 to 15 carbon atoms, an ether with 3 to 15 carbon atoms, a halogen atom and a benzene group

The conductive polymer is preferably polypyrrol, polythiophene, polyfuran, polyselenophene and derivatives thereof, is prepared into a film with a thickness of 0.01 to 5 μm, and can be freely controlled into a pattern size of 1 nm to several tens μm which can be processed by a lithography. The electric conductivity of the conjugated and conductive polymer prepared according to the inventive method is about 10²˜10⁸ Ω/cm², and the electric conductivity and mechanical strength depend on the concentration of oxidants, the time for synthesis and the temperature. Particularly, when pyrrol is used for the monomer, parameters such as reaction time, reaction temperature, reaction solvent, oxidants and the like influence the microstructure and electric conductivity of the conductive polymer synthesized. Also, since pyrrol has a relatively low oxidation potential and high vapor pressure, it can be chemically reacted in a vapor phase with easy.

Basically, the photolithography by a self-assembly according to the inventive method need not use photoresists and developers, and its process is simple and a circuit is formed through a bottom-up method. A self-assembly through a bottom-up method means a process of assembling monomeric chemical materials into the required shape, that is, forming a required shape while synthesizing monomers into large molecules, as opposed to that of forming a required shape after preparing a film. That is, it is compared to a process of forming an organ or tissue while maintaining divisional growth of small cells. This technique using a bottom-up method constitutes a nucleus for nano materials and nano processing and thus become a technical field on which many interests are focused.

Specifically, a substrate of silicon, glass or plastic is coated with a photosensitive inorganic oxidant (catalyst or oxidant) in the thickness of several nm. A photomask having a circuit pattern is placed on the coated substrate and, then, the substrate is irradiated with UV light which is selective to the inorganic oxidant on the substrate to thereby form the primary circuit. The substrate on which the primary circuit of the photosensitive inorganic oxidant is formed is placed in a CVD chamber and contacted with monomers in a vapor phase, which enable the chemical polymerization on the surface of the substrate and the formation of polymeric thin film selectively on the portion exposed to and the portion non-exposed to UV light. Thus, the polymeric film prepared by the inventive method is formed selectively on the portion exposed to and the portion non-exposed to UV light by a self-assembly process.

In the inventive method, the self-assembled polymer is synthesized in a vapor phase totally, which is contrasted with the traditional photoresist process which is a wet process. In the inventive method, the monomers in a vapor phase is polymerized into a polymeric material on the surface of the substrate coated with the photosensitive inorganic oxidant (oxidant or catalyst) by contacting the monomers with the surface, which is called a vapor phase polymerization or a vapor phase deposition. The thickness of this film can be freely controlled from several nm to several tens nm. Therefore, the present invention is directed to a method of preparing a thin film of polymer by a vapor phase polymerization and the circuit prepared by the method. More specifically, the present process is divided into several steps of coating a surface of substrate with an inorganic oxidant in the thickness of several nm and drying the surface in a drier; exposing the substrate on which a mask is placed to UV light to form a circuit on the coated substrate; polymerizing the monomers in a vapor phase selectively on the surface of the substrate by contacting the monomers with the substrate; and washing the non-reacted materials and oxidants after completing the polymerization. That is, in contrast with the traditional photolithographic process which comprises the steps of photoresist coating→drying→exposing to a light→developing→drying→forming a circuit, the inventive method by a self-assembly lithography comprises coating with photosensitive inorganic oxidants→drying→exposing→to a light polymerization (CVD, vapor phase polymerization)→washing →forming a circuit

Recently, techniques for patterning a circuit using a micro contact printing process, a screen printing process, an ink-jet printing process, etc are practiced. The present patterning method by a self-assembly can also adopt such printing techniques. Where the micro contact printing process is applied to the inventive method of patterning a circuit by a self-assembly, a circuit of thin film in several nm is formed by the micro contact printing process of photosensitive inorganic oxidants and, then, the circuit is contacted with vapor phase monomers in a chamber for vapor phase reaction as shown above. Thus, the vapor phase polymerization is set up selectively on only the portion which has the photosensitive inorganic oxidant in the surface of the substrate, resulting in forming the circuit of polymeric thin film. Although a resolution of the circuit prepared by a self-assembly is not good, the patterning of polymeric thin film can be simply practiced. Likewise, the screen printing process and the ink-jet printing process can be adapted to the inventive method. In this case, photosensitive inorganic oxidants are used in the process of printing, and vapor phase polymerization can be carried out for the patterning of polymeric thin film.

In summary, the self-assembly process for patterning a circuit using a micro contact printing process comprises the following steps in the order of forming a pattern of photosensitive inorganic oxidants by the micro contact printing process→drying→polymerization (CVD, vapor phase polymerization)→washing→forming a circuit. The self-assembly process for patterning a circuit using a screen printing process comprises the following steps in the order of forming a pattern of photosensitive inorganic oxidants by the screen printing process→drying→polymerization (CVD, vapor phase polymerization)→washing→forming a circuit. The self-assembly process for patterning a circuit using an ink-jet printing process comprises the following steps in the order of forming a pattern of photosensitive inorganic oxidants by the ink-jet printing process→drying→polymerization (CVD, vapor phase polymerization)→washing→forming a circuit.

The process for the preparation of polymer by a vapor phase polymerization can be performed under an atmosphere or vacuum condition and within the range of 10° C. to 100° C. The materials which are reactive with the photosensitive oxidants or catalysts are used as the organic monomer. Preferably, heterocycles such as pyrrol, thiophene, aniline, etc. are used. Where necessary, acrylmonomer, imide and the like can be used as the monomer. In particular, when thin film of polyacrylic polymers is formed by using acrylic monomers, the process of vapor phase polymerization is carried out in a CVD chamber with a irradiation of UV light.

Particularly, where the monomer of heteocycle such as pyrrol, thiophene or aniline is used, a circuit of conductive polymer such as polypyrrol, polythiophene, polyaniline and the like can be constructed and patterned. That is, a lithography which is constituted by a conductive polymer is practiced. Polypyrrol and polythiophene can be easily synthesized and the synthesized polymer has a high electric conductivity and is stable under atmosphere and, thus, many studies have been made for its application. Also, in the aspect of thermal property, it can stably maintains a feature of thin film up to about 350° C.

Up to now, an electro-chemical polymerization and a chemical oxidative polymerization are known as a method of synthesizing the conductive polymer compounds of conductive polymer. However, the compounds are not melted or dissolved as shown in other conjugated and conductive polymer materials and thus it is difficult to process them into a shape of film and the other forms. Thus, the compounds have many limitations in their applications.

The process by a vapor phase polymerization in the present invention can fully complement the shortcomings discussed above and has an advantage of synthesizing polymer in a vapor phase even under atmosphere. Recently, it is reported that conductive polymer can extend its application to semiconductor IC chips having an anti-static electricity, carriers of precise electronic devices (for examples, shipping tray, carrier tape, etc.) and display materials. In particular, an application as a material for shielding electromagnetic waves becomes prominent. Therefore, the construction prepared by the inventive method has a function of preventing static electricity and also functions as a conductor and, thus, is suitable for patterning a circuit of transparent conductive material. Where necessary, it can exert a good function as a material of electrode which replaces an electrode of ITO, copper or aluminum, which provides a breakthrough technique of patterning a circuit to simply solve the problem of metal patterning using the traditional complex process.

As shown above, the inventive method of patterning a circuit using a self-assembly lithography is a bottom-up process which produces various patterns of polymeric thin film through a simple CVD by a self-assembly without using photoresist, developer, etc., compared with the prior photo lithographic method using a top-down process which patterns a circuit with a use of photoresist, developer, etc. Thus, the inventive method provides a new method which shortens the processing time more than 50% and also attains a reduction of manufacturing coat over 50%. Further, since the prior wet process is replaced with a dry process, environmental conditions can be dramatically improved and an ultrafine structure in a size of nanometer can be simply constructed. In addition, the inventive method makes it possible free patterning of conductive polymer by a vapor phase deposition which produces a good feature of thin film and can freely control an electric conductivity and, thus, provides a way to replace some of the traditional metal process.

Further, the present invention provides a self-assembled lithographic circuit prepared according to the inventive method.

In the present self-assembled lithographic circuit, it is preferred that the self-assembled polymer has a chemical structure of the following formula 1:

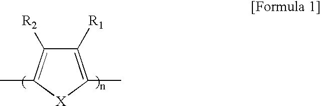

wherein, X is selected from the group consisting of S, O, Se and NH; each of R1 and R2 is selected from the group consisting of a hydrogen atom, an alkyl group containing 3 to 15 carbon atoms, an ether containing 3 to 15 carbon atoms, a halogen atom and a benzene group.

In addition, the present invention provides a method of preparing an electrode circuit wherein the self-assembled lithographic circuit is used as a material for an electronic part, a flat panel display or a semiconductor device. That is, the inventive method of the preparation of circuits can provide a new technique for the construction of electronic part, display, etc.

The pattern of conductive polymer prepared according to the inventive method can have a static electricity, an anti-static function and a function of shielding electromagnetic wave and also can function as a conductor. Thus, where manufactured into a circuit of conductive film which replaces a metal as well as an insulating film, it can be used as a pattern material of a functional film or transparent electrode. In general, it is suitable for a photolithography for the construction of semiconductor circuit and a patterning for the formation of display circuit.

In the prior art, a thin film is prepared by spin coating on a surface of substrate of a glass, plastic, metal, etc. the photosensitive polymers which have been blended after synthesized and then blended. Thereafter, before producing a final circuit pattern on the surface of substrate, five or six steps of drying, exposing, developing, drying, etc should be performed. Particularly, there are several problems that the steps of coating and developing are carried out in a wet process, environmental contamination is high due to the use of a large amount of organic solvents, and processing time is long. However, since the new process according to the present invention does not use such photoresist and developer art and is carried out in a dry process for a short time under clean condition, the environmental problem and the manufacturing cost can be reduced ⅔ times or more.

The technique of the present invention can be applied to a micro contact printing process, a screen printing process, an ink-jet printing process, etc. as described above. In this case, the processing time and the manufacturing cost in a photo lithographic process can be considerably reduced.

Hereinafter, the present invention is illustrated in more detail by examples.

The following examples are intended to be illustrative and do not limit the scope of the present invention to them.

### Example 1

The oxidant of ferric chloride (FeCl₃)t was dissolved in methyl alcohol in an amount of 2% by weight. Silicon wafer substrate was coated with said solution in the thickness of several nanometer and dried for 2 to 3 minutes at a temperature of about 60 to 70° C. A photomask was laid on the silicon wafer coated with said oxidant solution and 248 nm Eximer laser was exposed to the wafer. A pattern was formed selectively on the portion exposed and the portion non-exposed to the laser. The patterned substrate was placed in a CVD chamber which was designed to produce saturated pyrrol monomers for about 20 to 30 seconds, which enable the monomers to chemically react for a self-assembly. As a result of this, a polymer polypyrrol in a thickness of several tens nm was formed only on the portion non-exposed to the laser to thereby obtain a silicon wafer patterned by the polymeric polypyrrol.

To remove non-reacted materials, the patterned substrate was washed by a methanol and dried at 80° C. for five minutes. At this time, the temperature of washing bath was 20° C. A transparent brown circuit board patterned by the polymer of polypyrrol was produced. The thickness of the polymeric thin film was about 10 to 20 nm, the linewidth of the film was 100 nm and the sheet resistance of the film was about 10⁴ Ω/cm². The film was stable to an organic solvent such as isopropyl alcohol, etc. and a change of physical property was not occurred at a high temperature of 300° C. or more.

### Example 2

The oxidant of ferric chloride (FeCl₃) was dissolved in a mixture of methyl alcohol, 2-butyl alcohol and ethylselesolve in a ratio of 4:3:3 and a host polymer of polyvinyl alcohol with a molecular weight of 80,000 to 129,000 was added thereto in a total weight ratio of 1%. Thereafter, a silicon wafer substrate was coated with the mixture by a spin coating and dried for 2 to 3 minutes at a temperature of about 60 to 70° C. A photomask was laid on the silicon wafer coated with the oxidant and 365 nm UV light was exposed to the wafer. A pattern was formed selectively on the portion exposed and non-exposed to the light. After placing the patterned substrate in a CVD chamber which was designed to produce saturated thiophene monomers, the procedure described in Example 1 was carried out. After the steps of washing and drying, a circuit board patterned by a transparent blue polymer of polythiophene was obtained. The thickness of the polymeric thin film was about 10 to 20 nm, the linewidth of the film was 100 nm and the sheet resistance of the film was about 10³ Ω/cm². The film was stable to an organic solvent such as MEK, etc. and a change of physical property was not occurred at a high temperature of 350° C. or more. The uniformity of the film was high and the hardness of conductive polymeric thin film was improved.

### Example 3

The oxidant of Cu(ClO₄)₂.6H₂O was dissolved in methyl alcohol in an amount of 3% by weight. Glass substrate was coated with the solution by a spin coating and dried for 2 to 3 minutes at a temperature of about 60 to 70° C. The coated substrate was placed in a closed chamber which produces saturated pyrrol monomers for about 20 to 30 seconds, which enable the monomers to chemically react for a self-assembly. Thereafter, the substrate prepared above was exposed to 365 nm of UV light and non-reacted materials were washed by water. As a result of this, a transparent brown film pattern of conductive polymer was produced. The thickness of the polymeric thin film was about 30 to 50 nm, the linewidth of the film was 5 μm and the sheet resistance of the film was about 10³ Ω/cm². The film was stable to an organic solvent such as isopropyl alcohol, etc. and an electric conductivity was not changed at a high temperature of 300° C. or more.

### Example 4

The procedures described in Example 1 were carried out, except that Irgacure 184 was used as an oxidant, a polyester film was used as a substrate material, acryl monomer was used as a monomer for a self-assembly, and 365 nm of UV light was irradiated. As a result of this, a circuit pattern of polyacryl polymer in a thickness of 10 nm with a linewidth of about 1 μm could be obtained. The circuit was electrically insulated.

### Example 5

The procedures described in Example 1 were carried, except that the patterned circuit was produced after a chemical reaction for about 30 to 40 minutes in a CVD chamber which was designed to produce 2,3-dihydrothio-3,4-dioxin monomers. At this time, the reaction temperature was 45° C. The thickness of the film was about 80 to 100 nm, the linewidth of the film was 10 μm, the sheet resistance of the film was about 550 Ω/cm² and the electric conductivity was extremely high. Due to the high electric conductivity, the film can be used for metal circuit pattern and a part of metal work in a semiconductor process can be replaced by the polymeric thin film.

### Example 6

The procedures described in Example 1 were carried, except that the material of substrate was PET plastics.

### Example 7

The procedures from the coating of photosensitive oxidant to the exposure of UV light described in Example 1 were carried out by a micro contact printing process, thereby forming a circuit. Thereafter, the self-assembly polymerization was effected in a closed vapor phase polymerization chamber by contacting the circuit with vaporized pyrrol monomers. Polymeric thin film was selectively formed only on the portion coated with the oxidant according to the micro contact printing process. Polycarbonate film was used as a substrate and 30 μm of circuit pattern could be formed on it.

### Example 8

The procedures from the coating of photosensitive oxidant to the exposure of UV light described in Example 7 was carried was carried out by an ink-jet printing process, thereby forming a circuit. Thereafter, the self-assembly polymerization was effected in a closed vapor phase deposition chamber by contacting the circuit with vaporized pyrrol monomers. Polymeric thin film was selectively formed only on the portion coated with the oxidant according to the ink-jet printing process.

### Example 9

The procedures described in Example 1 were carried, except that the host polymer of PVA was added to the photosensitive oxidant in an amount of 5% by weight in order to enhance an adhesion.

### Example 10

The procedures described in Example 1 were carried, except that distilled water was used for the washing step.

### Example 11

The procedures described in Example were carried out, except that aniline monomer was used for the formation of polymeric thin film. A circuit pattern with the linewidth of 5 μm of polyaniline was produced.

The polymer circuit pattern prepared according to said Examples can be electrically insulated or have a property of conductor with a electric conductivity according to the condition of procedure and the kinds of vapor phase monomers used in the self-assembly process. Therefore, the electric conductivity can be freely controlled within a range of 200Ω/□ to 10⁸Ω/□. The static electricity and anti-static function can be provided to the circuit and the circuit can be used as an electrode material which is below a grade of resistance.

As shown above, the present invention provides a new photolithographic technique using a self-assembly process without using photoresist and developer which have been conventionally used for a photo lithography. Thus, when compared with a traditional method, the inventive method not only greatly reduce the cost of materials but also shorten the processing time more than 50%, thus resulting in the effect of reducing the manufacturing cost. Further, since the feature of thin film is excellent and the electric conductivity of it can be freely controlled, the present invention can be diversely applied to a photo lithography of electrode, circuit board, semiconductor, etc.

While the present invention has been described with reference to the particular illustrative embodiments, it is not to be restricted by the embodiments but only by the appended claims. It is to be appreciated that those skilled in the art can change or modify the present invention without departing from the scope and spirit of the present invention.

What is claimed is:

1. A method for patterning of conductive polymer, which comprises the steps of:
i) coating a substrate with a photosensitive inorganic oxidant which acts as a catalyst or an oxidant in the thickness of nanometer (nm);
(ii) irradiating selective UV or visible light with a stepper to the coated substrate on which a photomask with a circuit pattern is placed to thereby form a primary circuit on the portion exposed to the UV or visible light;
(iii) contacting the substrate having the primary circuit with monomers in a phase of vapor and growing a polymeric thin film selectively on the portion exposed to and the portion non-exposed to the UV or visible light in a surface of the substrate to thereby complete the circuit patterning; and
(iv) washing the patterned substrate to thereby remove impurities or non-reacted materials.

2. The method according to claim 1, wherein the substrate is selected from the group consisting of glass, silicon, metal and plastics.

3. The method according to claim 2, wherein the plastic material is selected from the group consisting of polyester, polycarbonate, polyimide, polyethersulfone, TAC, COC polymer and polyester.

4. The method according to claim 1, wherein the photosensitive inorganic oxidant comprises copper oxidant or ferric (F⁺³) compound.

5. The method according to claim 4, wherein the photosensitive inorganic oxidant is selected from the group consisting of CuCl₃, Cu(ClO₄)₂.6H₂O, FeCl₃ and ferric p-toluene sulfonate.

6. The method according to claim 1, further comprising the step of adding other host polymer material to the photosensitive oxidant to improve the adhesion of the photosensitive oxidant.

7. The method according to claim 1, wherein the other host polymer material is selected from the group consisting of polybutylacrylate, polycarbonate, polyurethane, polyvinylchloride, polyvinylalcohol, polyester, methylcellulose and chitosan.

8. The method according to claim 6, wherein the host polymer material is added in an amount of 0.5 to 10% by weight, based on the total weight of the photosensitive oxidant.

9. The method according to claim 1, wherein the stepper uses an electron beam or a plasma.

10. The method according to claim 1, wherein the stepper irradiates UV or visible light with a wavelength of 100 to 500 nm.

11. The method according to claim 1, wherein the vapor phase monomers are selected from the group consisting of aniline, pyrrol, thiophene, furan, selenophene, 2,3-dihydrothio-3,4-dioxin and derivatives thereof.

12. The method according to claim 1, wherein the substrate having the primary circuit is contacted with vapor phase monomers in a chemical vapor deposition (CVD) chamber.

13. The method according to claim 12, wherein contacting the substrate having the primary circuit with vapor phase monomers to grow a self-assembly polymer is performed in such a manner that the monomers are vaporized in the CVD chamber and then is contacted with the oxidant-coated substrate.

14. The method according to claim 1, wherein the non-reacted materials are removed by washing the non-reacted materials with the organic solvent or water.

15. The method according to claim 1, wherein the organic solvent is selected from the group consisting of methanol, ethanol, acetone, etc.

16. The method according to claim 1, wherein each step of patterning a circuit is carried out by a non-continuous process or a continuous process.

17. The method according to claim 1, wherein the primary circuit of a photosensitive inorganic oxidant is formed by a contact printing process or an ink jet printing process, and the patterning is completed by selectively growing the polymeric thin film on only the circuit of the photosensitive inorganic oxidant on the surface of the oxidant coated substrate.

18. The self-assembled lithographic circuit having electrical conductivity which is prepared by the method of claim 1.

19. A self-assembled lithographic circuit, wherein the self-assembled polymer has a chemical structure of the following formula 1: 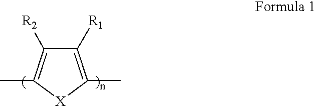
where, X is selected from the group consisting of S, O, Se and NH; each of R1 and R2 is selected from the group consisting of hydrogen, a hydrogen atom, an alkyl group containing 3 to 15 carbon atoms, an ether containing 3 to 15 carbon atoms, a halogen atom and a benzene group.

20. A method of forming an electrode circuit, wherein the self-assembled lithographic circuit prepared by the method of claim 18 is used as a material for an electronic part, a flat panel display or a semiconductor device.

21. A method of forming an electrode circuit, wherein the self-assembled lithographic circuit prepared by the method of claim 19 is used as a material for an electronic part, a flat panel display or a semiconductor device.
